(19) United States
(12) Patent Application Publication
(10) Pub. No.: US 2025/0280720 A1
(43) Pub. Date: Sep. 4, 2025

(54) Foldable Display Device

(71) Applicant: LG Display Co., Ltd., Seoul (KR)

(72) Inventor: Miyeon Seo, Seoul (KR)

(21) Appl. No.: 19/061,486

(22) Filed: Feb. 24, 2025

(30) Foreign Application Priority Data
Feb. 29, 2024 (KR) 10-2024-0029833

(51) Int. Cl. H10K 59/80; H10K 59/122; H10K 59/38; H10K 102/00

(52) U.S. Cl. CPC H10K 59/8792; H10K 59/122; H10K 59/38; H10K 2102/311

(57) ABSTRACT

Provided is a foldable display device. The foldable display device includes a flexible substrate which includes a plurality of sub pixels and includes a folding area and non-folding areas disposed on both sides of the folding area; a light emitting diode which is disposed on the flexible substrate and includes an anode, an emission layer, and a cathode; a bank which covers an edge of the anode to define an emission area; an encapsulation layer on the cathode; a plurality of color filters which is disposed on the encapsulation layer and corresponds to the plurality of sub pixels; and an over coating layer on the plurality of color filters. Each of the plurality of color filters disposed in the folding area includes at least one hole and the plurality of color filters has a reversed taper shape in the hole.

### CROSS-REFERENCE TO RELATED APPLICATION

This application claims the priority of Republic of Korea Patent Application No. 10-2024-0029833 filed on Feb. 29, 2024, which is hereby incorporated by reference in its entirety.

### BACKGROUND

### Field

The present disclosure relates to a foldable display device, and more particularly to a foldable display device which improves reflective visibility and improves a rainbow mura with excellent foldability.

### Description of the Related Art

Recently, as it enters an information era, a display field which visually expresses electrical information signals has been rapidly developed and in response to this, various display devices having excellent performances such as thin-thickness, light weight, and low power consumption have been developed. Specific examples of such a display device include a liquid crystal display device (LCD), a plasma display panel device (PDP), a field emission display device (FED), an organic light emitting display device (OLED), and the like.

Among them, the organic light emitting display device includes an anode, a cathode, and an organic emission layer disposed therebetween. However, the cathode is formed using a metal material having a high reflectance so that the external light is reflected by the metal material to deteriorate reflective visibility and a contrast ratio. Therefore, in order to reduce the reflection by the external light, a polarizer is disposed below a cover member to absorb the external light. The polarizer is a film having a predetermined level of light transmittance and absorbs external light and reflected light thereof to suppress the deterioration of the contrast ratio.

In the meantime, recently, a flexible display device which is manufactured to be capable of displaying images even though the flexible display device is bent or folded like papers is attracting attention as a next generation display device. The flexible display device is classified into an unbreakable display device having a high durability, a bendable display device which is bent without being broken, a rollable display device which is rolled, and a foldable display device which is folded. Such a flexible display device has advantages in terms of space utilization, interior, and designs and has various application fields.

In such a flexible display device, a structure in which a relatively thin coated polarization film is applied instead of a thick polarizer has been suggested. However, there are problems in that the thickness of the coated polarization film is also large and if the thickness is reduced, a function and a display quality of the coated polarization film are deteriorated.

Therefore, instead of the polarizer or the coated polarization film, a color filter on encapsulation layer structure has been proposed. The CoE structure of the related art is a structure in which the black matrix is disposed on the encapsulation layer so as to correspond to the non-emission area and the color filter is disposed so as to correspond to the emission area. According to the CoE structure, the thickness of the display device may be reduced and the transmittance is easily controlled so that external light and the reflected light are absorbed without degrading the luminous efficiency to improve the display quality. However, when the CoE structure is used in the flexible display device, there are problems in that the color filter is peeled off to degrade the durability and the rainbow mura is generated by the color filter to degrade the display quality.

### SUMMARY

In order to solve the problem of the CoE structure of the related art, a pull-back structure in which a width of the color filter is formed to be larger than a width of the corresponding emission area has been applied. However, when the pull-back structure is applied, a width of the bank is larger than the black matrix so that the bank is not fully covered by the black matrix to be exposed. Therefore, there is a problem in that the rainbow mura is caused by the exposed bank to degrade the display quality.

Therefore, an object to be achieved by the present disclosure is to provide a foldable display device which suppresses external light reflection and has excellent reflective visibility.

Another object to be achieved by the present disclosure is to reduce the thickness of the display device to be easily implemented as a foldable display device.

Another object to be achieved by the present disclosure is to provide a foldable display device which improves the rainbow mura even though a pull-back structure is applied.

Another object to be achieved by the present disclosure is to provide a foldable display device in which peeling between a color filter and a coating layer disposed above the color filter due to a stress generated during the folding is suppressed to suppress the degradation of the durability of the display device.

Objects of the present disclosure are not limited to the above-mentioned objects, and other objects, which are not mentioned above, can be clearly understood by those skilled in the art from the following descriptions.

According to an embodiment of the present disclosure, a foldable display device includes a flexible substrate which includes a plurality of sub pixels and includes a folding area and non-folding areas disposed on both sides of the folding area; a light emitting diode which is disposed on the flexible substrate and includes an anode, an emission layer, and a cathode; a bank which covers an edge of the anode to define an emission area; an encapsulation layer on the cathode; a plurality of color filters which is disposed on the encapsulation layer and corresponds to the plurality of sub pixels; and an over coating layer on the plurality of color filters, each of the plurality of color filters disposed in the folding area includes at least one hole and the plurality of color filters has a reversed taper shape in the hole.

Other detailed matters of the exemplary embodiments are included in the detailed description and the drawings.

According to the present disclosure, in the foldable display device, the external light reflection is suppressed, and the reflective visibility may be improved.

According to the present disclosure, in the foldable display device, a hole is formed to allow a color filter of the folding area to have a reversed taper shape to suppress the peeling and a crack of the color filter and the over coating layer to improve the durability of the panel.

According to the present disclosure, the foldable display device may improve the rainbow mura.

According to the present disclosure, in the foldable display device, the thickness of the display device is reduced to improve the foldability.

The effects according to the present disclosure are not limited to the contents exemplified above, and more various effects are included in the present specification.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a schematic plan view of a foldable display device according to an exemplary embodiment of the present disclosure;

FIG. 2 is a schematic cross-sectional view of II-II′ of FIG. 1 according to an exemplary embodiment of the present disclosure;

FIG. 3 is a schematic enlarged plan view of an area A of FIG. 1 according to an exemplary embodiment of the present disclosure;

FIG. 4 is a schematic cross-sectional view of VI-VI′ of FIG. 1 according to an exemplary embodiment of the present disclosure;

FIG. 5A is a schematic cross-sectional view of a foldable display device according to another exemplary embodiment of the present disclosure;

FIG. 5B is a graph illustrating a shear strain of a general display device during the folding as it is adjacent to a non-display area from a center of a folding area according to an exemplary embodiment of the present disclosure;

FIG. 6 is a schematic cross-sectional view of a foldable display device according to still another exemplary embodiment of the present disclosure;

FIG. 7 is a schematic enlarged plan view for a partial area of a foldable display device illustrated in FIG. 6 according to an exemplary embodiment of the present disclosure;

FIG. 8 is a schematic cross-sectional view of a foldable display device according to still another exemplary embodiment of the present disclosure;

FIG. 9 is a schematic cross-sectional view of a foldable display device according to still another exemplary embodiment of the present disclosure;

FIG. 10 is a schematic cross-sectional view of a foldable display device according to still another exemplary embodiment of the present disclosure;

FIG. 11 is a schematic cross-sectional view of a foldable display device according to still another exemplary embodiment of the present disclosure; and

FIG. 12 is a schematic cross-sectional view of a foldable display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a foldable display device according to exemplary embodiments of the present disclosure will be described in detail with reference to accompanying drawings.

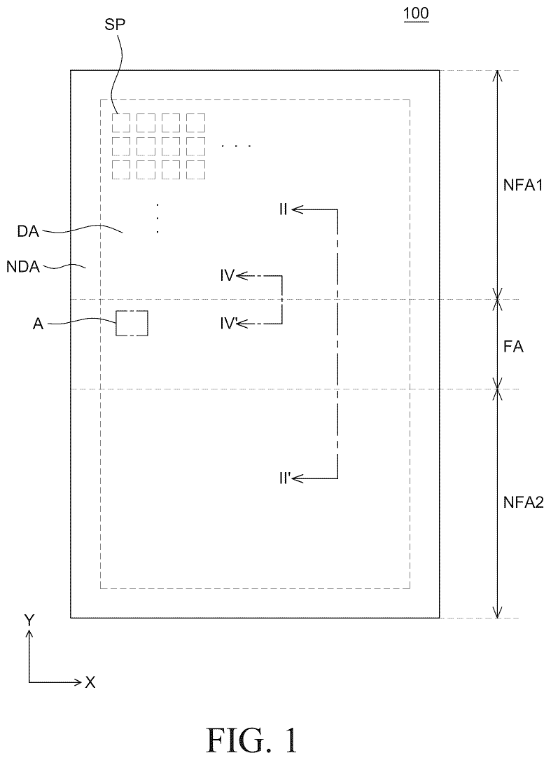

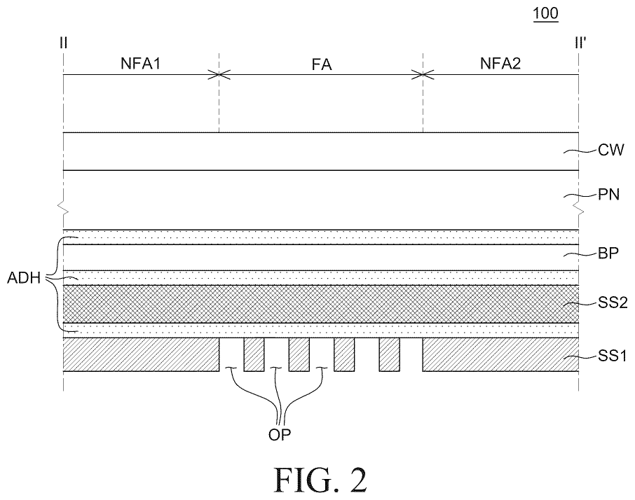

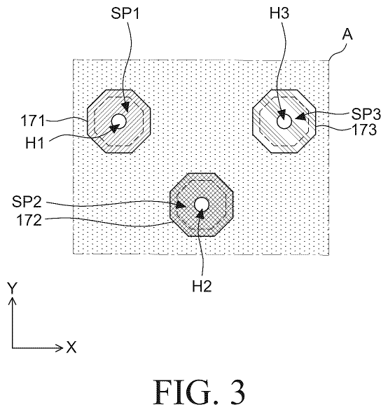

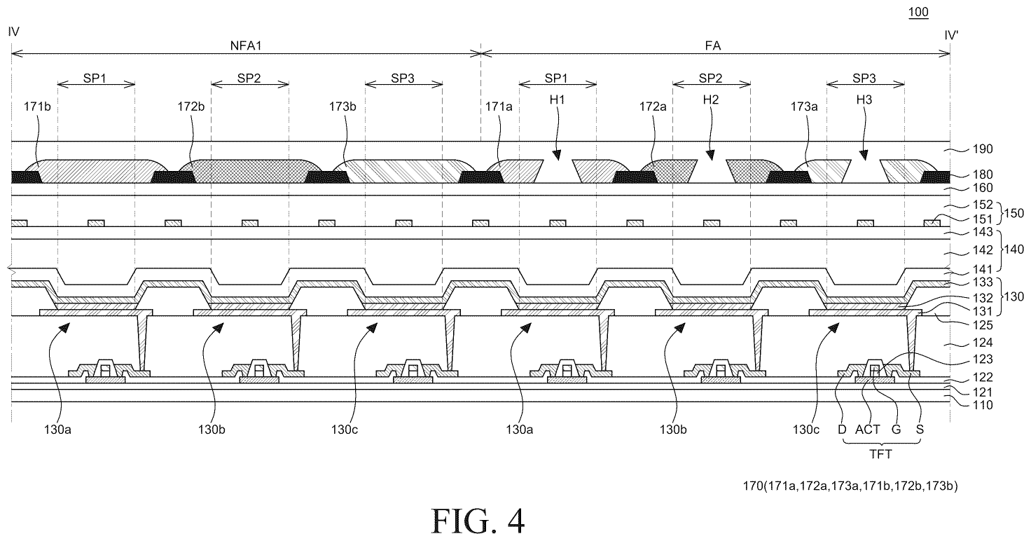

FIG. 1 is a schematic plan view of a foldable display device according to an exemplary embodiment of the present disclosure. FIG. 2 is a schematic cross-sectional view of II-II′ of FIG. 1 according to an exemplary embodiment of the present disclosure. FIG. 3 is a schematic enlarged plan view of an area A of FIG. 1 according to an exemplary embodiment of the present disclosure. FIG. 4 is a schematic cross-sectional view of VI-VI′ of FIG. 1 according to an exemplary embodiment of the present disclosure.

Referring to FIGS. 1 and 2, a foldable display device 100 according to the exemplary embodiment of the present disclosure includes a display panel PN, a cover window CW, a first support substrate SS1, a second support substrate SS2, a back plate BP, and an adhesive layer ADH. Hereinafter, for the convenience of description, the foldable display device 100 according to the exemplary embodiment of the present disclosure is assumed as an organic light emitting display device, but it is not limited thereto.

The display panel PN includes a display area DA and a non-display area NDA. Further, the display panel PN includes a folding area FA and non-folding areas NFA1 and NFA2. The display panel PN may be divided into a display area DA and a non-display area NDA depending on whether to display an image. Further, the display panel PN may be divided into a folding area FA and non-folding areas NFA1 and NFA2 depending on whether to be folded. Therefore, a partial area of the display panel PN may be a display area DA and also a folding area FA and the other partial area of the display panel PN may be a non-display area NDA and may also be the non-folding areas NFA1 and NFA2.

In the meantime, for the convenience of description, it is assumed that the foldable display device 100 according to the exemplary embodiment of the present disclosure is a foldable display device in which one folding area FA is disposed in only a partial area of the display area DA. However, the foldable display device 100 according to the exemplary embodiment of the present disclosure may be a display device in which a plurality of folding areas is disposed in the display area DA of the display panel PN, but is not limited thereto.

The display area DA is an area where a plurality of pixels are disposed to substantially display images. In the display area DA, a plurality of pixels which include an emission area to display images, a thin film transistor for driving the pixels, and a capacitor may be disposed. One pixel may include a plurality of sub pixels SP. The sub pixel SP is a minimum unit which configures the display area and each sub pixel SP may be configured to emit light of a specific wavelength band. For example, each of the sub pixels SP may be configured to emit red light, green light, blue light, or white light.

The non-display area NDA is disposed so as to enclose the display area DA. The non-display area NDA is an area where images are not substantially displayed and various wiring lines and driving ICs for driving the pixels and the driving elements disposed in the display area DA are disposed therein.

As described above, the display panel PN may be defined as a folding area FA and non-folding areas NFA1 and NFA2 depending on whether to be foldable. The display panel PN includes one folding area FA which is foldable and non-folding areas NFA1 and NFA2 excluding the folding area. The folding area FA is an area which is folded when the foldable display device 100 is folded and is folded in accordance with a specific radius of curvature with respect to a folding axis. Here, the folding axis may be formed in the X-axis direction. The non-folding areas NFA1 and NFA2 may be located on both sides of the folding area FA along the folding direction. Here, the folding direction may refer to a Y-axis direction which is perpendicular to the folding axis. When the folding area FA is folded with respect to the folding axis, the folding area FA may form a part of a circle or an oval. At this time, a radius of curvature of the folding area FA may refer to a radius of a circle or an oval formed by the folding area FA.

The non-folding areas NFA1 and NFA2 are areas which are not folded when the foldable display device 100 is folded. That is, the non-folding areas NFA1 and NFA2 maintain a plan surface state when the foldable display device 100 is folded. The non-folding areas NFA1 and NFA2 may extend from both sides of the folding area FA along the folding direction. At this time, the folding area FA may be defined between the non-folding areas NFA1 and NFA2. The non-folding areas NFA1 and NFA2 include a first non-folding area NFA1 and a second non-folding area NFA2. The first non-folding area NFA1 extends from one side of the folding area FA and the second non-folding area NFA2 extends from the other side of the folding area FA. When the foldable display device 100 is folded with respect to the folding axis, the first non-folding area NFA1 and the second non-folding area NFA2 may overlap each other.

The display panel PN includes a flexible substrate, a driving thin film transistor, a display element, or the like. In the display panel PN, the flexible substrate on which the driving thin film transistor and the display element are formed may be encapsulated by an encapsulation unit. The display panel PN includes a flexible substrate with a small thickness and a display element disposed on the flexible substrate to implement the flexibility.

The display element may be defined in different ways depending on a type of the display panel PN. For example, when the display panel PN is an organic light emitting display panel, the display element may be an organic light emitting diode which includes an anode, an emission layer, and a cathode. Further, the display panel PN may be an inorganic light emitting display device in which the light emitting diode is implemented by a light emitting diode based on an inorganic material. For example, the display panel PN may be a quantum dot display panel in which the light emitting diode is implemented by a quantum dot which is a self-emitting semiconductor crystal. The display panel PN will be described in detail below with reference to FIG. 4.

The cover window CW is disposed on the display panel PN. The cover window CW protects the display panel PN from the external impacts and scratches. Therefore, the cover window CW may be formed of a material which is transparent and has excellent impact resistance and scratch resistance. Further, the cover window CW protects the display panel PN from the moisture permeating from the outside. Therefore, the cover window CW may suppress the display panel PN from deteriorating to degrade the display quality.

The cover window CW may be implemented by a flexible plastic-based cover which is foldable, to ensure the thin thickness and the flexibility of the foldable display device 100. For example, the cover window CW may be a film formed of a polymer, such as polyimide, polyamide imide, polyethylene terephthalate, polymethyl methacrylate, polypropylene glycol, and polycarbonate. Alternatively, the cover window CW may be a film formed of a photoisotropic polymer such as cycloolefin (co)polymer, photoisotropic polycarbonate, or photoisotropic polymethyl methacrylate.

The cover window CW may have a multi-layered structure in which various functional layers are laminated. For example, the cover window CW may include various functional layers such as external light reflection reducing layer, a UV blocking layer, or a hard coating layer. Further, a touch panel which forms a touch sensor may be optionally disposed between the display panel PN and the cover window CW as needed.

In the meantime, the flexible substrate of the display panel PN has excellent foldability, but has a small thickness and has a rigidity lower than a glass substrate or a metal substrate. Therefore, when the flexible substrate is folded, it may be difficult to consistently maintain the shape and the flexible substrate may be sagged by various elements which are formed thereon. Accordingly, the first support substrate SS1, the second support substrate SS2, and the back plate BP are disposed below the display panel PN to support the flexible substrate and improve the impact resistance. The first support substrate SS1, the second support substrate SS2, and the back plate BP support the display panel PN there below to suppress sagging or deformation and protect the display panel PN from external impacts or foreign materials.

The first support substrate SS1 may be referred to as a plate bottom or a bottom plate. The first support substrate SS1 may be a plate which is foldable and has an excellent rigidity. The first support substrate SS1 may be formed with a material having a rigidity larger than that of the flexible substrate to support the display panel PN.

The first support substrate SS1 may be formed of stainless steel (SUS), stainless steel containing metals such as nickel (Ni), or a metal material such as iron (Fe), aluminum (Al), or magnesium (Mg). Desirably, the stainless steel (SUS) may be applied for the first support substrate SS1. For example, the stainless-steel SUS has a high restoring force and rigidity so that even though the thickness of the first support substrate SS1 is reduced, the high rigidity may be maintained. Therefore, the first support substrate SS1 supports the display panel PN and reduces an overall thickness of the foldable display device 100 to reduce a radius of curvature of the folding area FA. However, the first support substrate SS1 is not limited thereto and may be formed of a polymer such as polymethylmetacrylate (PMMA), polycarbonate (PC), polyvinylalcohol (PVA), acrylonitrilebutadiene-styrene (ABS), polyethylene terephthalate (PET), silicone, or polyurethane (PU).

A thickness of the first support substrate SS1 may be 90 μm to 220 μm. When the thickness of the first support substrate SS1 is smaller than 90 μm, the first support substrate is too thin so that the first support substrate may not effectively support the display panel PN to be sagged. Further, if the thickness of the first support substrate SS1 is larger than 220 μm, when the foldable display device 100 is folded, a stress applied to the display panel PN is increased, which causes the crack and reduces the restoring force to cause the plastic deformation, and does not satisfy the folding reliability.

The first support substrate SS1 may include a plurality of opening patterns OP formed so as to correspond to the folding area FA of the foldable display device 100. The foldable display device 100 may be folded or unfolded by increasing an elastically deformed section by the plurality of opening patterns OP formed in the folding area FA. For the convenience of description, even though in FIG. 2, it is illustrated that five opening patterns OP are formed, it is not limited thereto.

The plurality of opening patterns OP may be formed on the first support substrate SS1 so as to correspond to the folding area FA. That is, the plurality of opening patterns OP may be holes which pass through the first support substrate SS1 in a thickness direction. When the foldable display device 100 is folded, the stress is concentrated on the folding area FA. The plurality of opening patterns OP may disperse the stress concentrated on the folding area FA during the folding. As described above, as the plurality of opening patterns OP is formed in a position corresponding to the folding area FA, it is advantageous in that the foldable display device 100 is easily folded and the restorability is excellent.

Each of the plurality of opening patterns OP may be formed to extend along a direction parallel to the folding axis to be long. That is, each of the plurality of opening patterns OP may be formed to extend long along the same direction as the folding axis. Therefore, each of the plurality of opening patterns OP may be formed to be parallel to the folding axis in the form of bar in the plan view. In the meantime, each of the plurality of opening patterns OP may continuously extend to the non-display area across the display area DA without being disconnected, along the same direction as the folding axis, but is not limited thereto.

The second support substrate SS2 is disposed on the first support substrate SS1. The second support substrate SS2 may be referred to as a plate top or a top plate. The second support substrate SS2 may enhance the rigidity of the display panel PN and suppress the plurality of opening patterns OP formed in the first support substrate SS1 from being visible through the display panel PN. The second support substrate SS2 may be excluded as needed.

In the meantime, in the drawing, it is illustrated that the second support substrate SS2 has a thickness similar to that of the first support substrate SS1, but it is not limited thereto. That is, the second support substrate SS2 may have a thickness smaller than that of the first support substrate SS1. At this time, the second support substrate SS2 may be formed of stainless steel (SUS), stainless steel containing metals such as nickel (Ni), or a metal material such as iron (Fe), aluminum (Al), or magnesium (Mg). Further, the second support substrate SS2 is not limited thereto and may be formed of a polymer such as polymethylmetacrylate (PMMA), polycarbonate (PC), polyvinylalcohol (PVA), acrylonitrilebutadiene-styrene (ABS), polyethylene terephthalate (PET), silicone, or polyurethane (PU). Further, the second support substrate SS2 may be formed of the same material as the first support substrate SS1, but is not limited thereto.

The back plate BP may be disposed between the display panel PN and the second support substrate SS2. The back plate BP may be further attached onto a back surface of the display panel PN to further support the thin film type display panel PN, but may be excluded as needed. The back plate BP may suppress the plurality of opening patterns OP provided in the first support substrate SS1 from being visible through the display panel PN.

The back plate BP may be formed of a polymer such as polyimide (PI), polymethylmetacrylate (PMMA), polycarbonate (PC), polyvinylalcohol (PVA), acrylonitrilebutadiene-styrene (ABS), polyethylene terephthalate (PET), silicone, or polyurethane (PU), but is not limited thereto.

The first support substrate SS1, the second support substrate SS2, and the back plate BP are attached to each other by means of at least one adhesive layer ADH. Referring to FIG. 2, the adhesive layer ADH includes a first adhesive layer to a third adhesive layer. The first adhesive layer is disposed on the first support substrate SS1 to attach the first support substrate SS1 and the second support substrate SS2. The second adhesive layer is disposed on the second support substrate SS2 to attach the second support substrate SS2 and the back plate BP. The third adhesive layer is disposed on the back plate BP to attach the back plate BP and the display panel PN. In the meantime, even though in FIG. 2, it is illustrated that the adhesive layer ADH includes first to third adhesive layers, the second adhesive layer and the third adhesive layer may be omitted depending on whether to use the second support substrate SS2 and the back plate BP. The adhesive layer ADH may be formed of a transparent adhesive member such as an optically clear resin (OCR) or an optically clear adhesive (OCA), but is not limited thereto.

Hereinafter, the display panel of the present disclosure will be described in detail with reference to FIGS. 3 and 4. FIG. 3 is a schematic enlarged plan view of an area A of FIG. 1. The area A of FIG. 1 is one unit pixel and includes a plurality of sub pixels.

Referring to FIG. 3, one unit pixel includes a plurality of sub pixels SP1, SP2, and SP3. A sub pixel is an element which displays one color and includes an emission area where light is emitted and a non-emission area where light is not emitted, but in the specification, only the emission area where the light is emitted is defined as a sub pixel. Referring to FIG. 3, one unit pixel may include a first sub pixel SP1, a second sub pixel SP2, and a third sub pixel SP3. For example, the first sub pixel SP1 and the third sub pixel SP3 are disposed in a first direction (an x-axis direction). The second sub pixel SP2 is disposed along the first direction to be spaced apart from the first sub pixel SP1 and the third sub pixel SP3 in a second direction (a y-axis direction), but the present disclosure is not limited thereto. The first sub pixel SP1, the second sub pixel SP2, and the third sub pixel SP3 may display different colors and some sub pixels may display the same color as needed. In the meantime, any one of the first sub pixels SP1, the second sub pixels SP2, and the third sub pixels SP3 may be two or more to be disposed. For example, one unit pixel may include one first sub pixel SP1, two second sub pixels SP2, and one third sub pixel SP3.

Each of the first sub pixel SP1, the second sub pixel SP2, and the third sub pixel SP3 may be any one of a red sub pixel, a green sub pixel, and a blue sub pixel. For example, the first sub pixel SP1 is a red sub pixel, the second sub pixel SP2 is a green sub pixel, and the third sub pixel SP3 may be a blue sub pixel. At this time, two second sub pixels SP2 are configured to be disposed in a pentile structure. In the pentile structure, the second sub pixel SP2 which is green may have a smaller area than the first sub pixel SP1 which is red and the third sub pixel SP3 which is blue, in consideration of the luminance and the color temperature. Hereinafter, the foldable display device 100 according to the exemplary embodiment of the present disclosure will be described under the assumption that the first sub pixel SP1 is a red sub pixel, the second sub pixel SP2 is a green sub pixel, and the third sub pixel SP3 is a blue sub pixel. However, colors of the sub pixels are described as an example for the convenience of description so that the present disclosure is not limited thereto.

In FIG. 3, it is illustrated that the plurality of sub pixels SP1, SP2, and SP3 has an octagonal shape, but it is not limited thereto and the shape of the sub pixels may be changed in various shapes. For example, each sub pixel may have a circular shape, an oval shape, and a polygonal shape other than the octagonal shape.

Further, even though in FIG. 3, the plurality of sub pixels SP1, SP2, and SP3 disposed in the folding area FA is illustrated, the plurality of sub pixels SP1, SP2, and SP3 may be disposed also in the non-folding areas NFA1 and NFA2 with the same shape. Accordingly, the plurality of sub pixels SP1, SP2, and SP3 disposed in the folding area FA and the plurality of sub pixels SP1, SP2, and SP3 disposed in the non-folding areas NFA1 and NFA2 have the substantially same placement, shape, and configuration. However, as it will be described below, the plurality of sub pixels SP1, SP2, and SP3 disposed in the folding area FA and the plurality of sub pixels SP1, SP2, and SP3 disposed in the non-folding areas NFA1 and NFA2 may have different shapes of the color filters 171, 172 and 173.

Referring to FIG. 4, the display panel of the foldable display device 100 according to the exemplary embodiment of the present disclosure includes a flexible substrate 110, a thin film transistor TFT, an organic light emitting diode 130, an encapsulation layer 140, a touch sensor unit 150, a plurality of color filters 170, and a black matrix 180.

The flexible substrate 110 is a base member for supporting various components included in the display panel and may be formed of an insulating material. The flexible substrate 110 is formed of an insulating material having a very small thickness to implement the flexibility. For example, the flexible substrate may be an insulating plastic substrate selected from polyimide, polyethersulfone, polyethylene terephthalate, and polycarbonate, but is not limited thereto.

A first buffer layer 121 may be disposed on the flexible substrate 110 to suppress permeation of oxygen or moisture. The first buffer layer 121 may be formed as a single layer and may be formed with a multi-layered structure as needed.

On the first buffer layer 121, a thin film transistor TFT including a gate electrode G, an active layer ACT, a source electrode S, and a drain electrode D is disposed. The thin film transistor TFT is disposed in each area of the first sub pixel SP1, the second sub pixel SP2, and the third sub pixel SP3. In FIG. 4, only a driving thin film transistor, among various thin film transistors which may be included in the foldable display device 100, is illustrated for the convenience of description. Further, it is described that the thin film transistor TFT has a coplanar structure as an example in FIG. 4, but the present disclosure is not limited thereto and a thin film transistor TFT having an inverted staggered structure may also be used.

For example, the active layer ACT is disposed on the first buffer layer 121 and a gate insulating layer 123 is disposed on the active layer ACT to insulate the active layer ACT and the gate electrode G from each other. Further, an interlayer insulating layer 122 is disposed on the first buffer layer 121 to insulate the gate electrode G from the source electrode S and the drain electrode D. The source electrode S and the drain electrode D which are in contact with the active layer ACT are formed on the interlayer insulating layer 122. A planarization layer 124 may be disposed on the thin film transistor TFT. The planarization layer 124 planarizes an upper portion of the thin film transistor TFT. The planarization layer 124 may include a contact hole which electrically connects the thin film transistor TFT and the anode 131 of the organic light emitting diode 130.

The organic light emitting diode 130 is disposed on the planarization layer 124. The organic light emitting diode 130 includes a first organic light emitting diode 130a disposed in the first sub pixel SP1, a second organic light emitting diode 130b disposed in the second sub pixel SP2, and a third organic light emitting diode 130c disposed in the third sub pixel SP3. Each organic light emitting diode 130a, 130b, 130c includes an anode 131, an organic emission layer 132, and a cathode 133.

The anode 131 is disposed on the planarization layer 124. The anode 131 is disposed so as to correspond to each of the plurality of sub pixels SP1, SP2, and SP3. The anode 131 is formed of a conductive material having a high work function to supply holes to the organic emission layer 132. The anode 131 may be a transparent conductive layer which is formed of transparent conductive oxide (TCO). For example, the anode 131 may be formed by one or more selected from transparent conductive oxides such as indium tin oxide (ITO), indium zinc oxide (IZO), indium tin zinc oxide (ITZO), tin oxide (SnO2), zinc oxide (ZnO), indium copper oxide (ICO), and aluminum:zinc oxide (Al:ZnO, AZO), but is not limited thereto. When the foldable display device 100 is driven as a top emission type, the anode 131 may further include a reflection layer which reflects light emitted from the organic emission layer 132 toward the cathode 133. The anode 131 may be separately formed for each of the first sub pixel SP1, the second sub pixel SP2, and the third sub pixel SP3.

A bank 125 is disposed on the anode 131 and the planarization layer 124. The bank 125 may cover an edge of the anode 131 of the organic light emitting diode 130 to define an emission area. That is, the bank 125 may divide the plurality of sub pixels SP1, SP2, and SP3. The bank 125 may be formed of an insulating material which insulates anodes 131 of adjacent sub pixels SP1, SP2, and SP3 from each other. Further, the bank 125 may be configured by a black bank having a high light absorption rate to suppress color mixture between adjacent sub pixels SP1, SP2, and SP3. For example, the bank 125 may be formed of a polyimide resin, an acrylic resin, or a benzocyclobutene resin, but is not limited thereto.

The cathode 133 is disposed on the anode 131. The cathode 133 may be formed of a metal material having a low work function to smoothly supply electrons to the organic emission layer 132. For example, the cathode 133 may be formed of a metal material selected from calcium (Ca), barium (Ba), aluminum (Al), silver (Ag), and alloys including one or more of them, but is not limited thereto. Referring to FIG. 4, the cathode may be formed on the anode 131 as one layer. That is, the cathode 133 may be formed in the first sub pixel SP1, the second sub pixel SP2, and the third sub pixel SP3 as a single layer. When the foldable display device 100 is driven as a top emission type, the cathode 133 is formed to have a very small thickness to be substantially transparent.

The organic emission layer 132 is disposed between the anode 131 and the cathode 133. The organic emission layer 132 is a layer in which electrons and holes are coupled to emit light. The organic emission layer of the first organic light emitting diode 130a is a red organic emission layer, the organic emission layer of the second organic light emitting diode 130b is a green organic emission layer, and the organic emission layer of the third organic light emitting diode 130c may be a blue organic emission layer.

In order to improve luminous efficiency of the organic light emitting diode 130, a hole injection layer, a hole transport layer, an electron transport layer, and an electron injection layer may be further included. For example, the hole injection layer and the hole transport layer may be disposed between the anode 131 and the organic emission layer 132 and the electron transport layer and the electron injection layer may be disposed between the organic emission layer 132 and the cathode 133. Further, a hole blocking layer or an electron blocking layer may be disposed to further improve a recombination efficiency of the holes and electrons in the organic emission layer 132.

The encapsulation layer 140 is disposed on the organic light emitting diode 130. The encapsulation layer 140 may cover the organic light emitting diode 130. The encapsulation layer 140 may protect the organic light emitting diode 130 from moisture, oxygen, and impacts of the outside. The encapsulation layer 140 may be formed with a multi-layered structure in which an inorganic layer formed of an inorganic insulating material and an organic layer formed of an organic material are laminated. For example, the encapsulation layer 140 may be configured by at least one organic layer and at least two inorganic layers and have a multi-layered structure in which the inorganic layers and the organic layer are alternately laminated, but is not limited thereto. For example, the encapsulation layer 140 may have a triple layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. Further, the organic layer 142 may be formed of one or more selected from epoxy resin, polyimide, polyethylene, and silicon oxycarbide (SIOC), but is not limited thereto.

The touch sensor unit 150 (e.g., a circuit) is disposed on the encapsulation layer 140 to impart a touch sensing function to the foldable display device 100. The foldable display device 100 according to the exemplary embodiment of the present disclosure includes a touch sensor unit 150 with a structure in which the touch electrode 151 is formed on the encapsulation layer 140, rather than a structure in which a touch panel of the related art in which a touch electrode is formed on a separate base member is disposed above the organic light emitting diode by means of the adhesive member. As the touch sensor unit 150 is directly formed on the encapsulation layer 140, the adhesive member which attaches the touch sensor unit 150 and the organic light emitting display panel is omitted so that the thickness of the foldable display device 100 may be reduced.

The touch sensor unit 150 includes a touch electrode 151 and a touch protection layer 152. The touch electrode 151 may be directly formed on the encapsulation layer 140 without using an adhesive member. The touch electrode 151 is an electrode which senses a touch input and may be configured by a sensing electrode and a driving electrode and may detect a touch coordinate by sensing a change of the capacitance between the sensing electrode and the driving electrode. For example, the driving electrode is disposed on the second inorganic layer 143 and the sensing electrode may be disposed on the same plan surface as the driving electrode. As another example, a touch insulating layer is disposed on the driving electrode and the sensing electrode may be disposed on the touch insulating layer. The placement of the touch electrode 151 is not limited thereto and may vary as needed.

The touch electrode 151 is directly formed on the encapsulation layer 140 so that a distance between the organic light emitting diode 130 and the touch electrode 151 is too close so that a parasitic capacitance is generated between an electrode included in the organic light emitting diode 130 or the thin film transistor TFT and the touch electrode 151. Therefore, the touch sensitivity may be degraded. Therefore, the thickness of the encapsulation layer 140 may be appropriately adjusted to minimize or at least reduce the parasitic capacitance.

The touch electrode 151 may be formed of a transparent metal material which transmits the light, such as indium tin oxide (ITO) or indium zinc oxide (IZO). The touch electrode 151 may have various shapes such as a rectangular shape, an octagonal shape, a circular shape, or a rhombus shape.

The touch protection layer 152 is disposed on the touch electrode 151. The touch protection layer 152 suppresses the short-circuit or damage of the touch electrode 151 and planarizes an upper surface of the touch electrode 151. The touch protection layer 152 may be formed of a transparent insulating resin such as an acrylic resin, a polyester resin, an epoxy resin, or a silicon resin.

In the meantime, in FIG. 4, a structure in which the touch electrode 151 of the touch sensor unit 150 is in direct contact onto the encapsulation layer 140 has been disclosed, but it is not limited thereto. For example, the touch buffer layer is disposed between the encapsulation layer 140 and the touch sensor unit 150 and the touch electrode 151 may be disposed on the touch buffer layer. The touch buffer layer may suppress the damage of the encapsulation layer 140 and the organic light emitting diode 130 during a process of directly forming the touch electrode 151 on the encapsulation layer 140.

The touch buffer layer may be formed of an inorganic material having an excellent barrier property. Therefore, the permeation of moisture or oxygen may be minimized or at least reduced. For example, the touch buffer layer may be formed of an inorganic material, such as silicon nitride (SiNx), silicon oxide (SiOx), or aluminum oxide (AlOx), but is not limited thereto.

A second buffer layer 160 is disposed on the touch sensor unit 150. The second buffer layer 160 suppresses the permeation of the moisture or oxygen from the outside to protect the components of the foldable display device 100. The second buffer layer 160 may be formed of an inorganic material having an excellent barrier property. Therefore, the permeation of moisture or oxygen may be minimized or at least reduced. For example, the second buffer layer 160 may be formed of one or more inorganic materials selected from silicon nitride (SiNx), silicon oxide (SiOx), silicon oxy nitride (SiON), and aluminum oxide (Al2O3), but is not limited thereto. Further, the second buffer layer 160 may compensate for degradation of an adhesive strength between the plurality of color filters 170 and the black matrix 180 and the touch protection layer 152. That is, the second buffer layer 160 is disposed on the touch protection layer 152 to bond the plurality of color filters 170 and the black matrix 180 and the touch protection layer 152 to each other. The second buffer layer 160 may be omitted when the touch sensor unit 150 is disposed above the encapsulation layer 140 by means of the adhesive member or is disposed below the encapsulation layer 140. The plurality of color filters 170 and the black matrix 180 are disposed on the second buffer layer 160. The plurality of color filters 170 and the black matrix 180 are integrally formed on the same plan surface and absorb external light to minimize or at least reduce degradation of the visibility and a contrast ratio of the foldable display device 100 due to the external light.

The plurality of color filters 170 and the black matrix 180 are disposed on the second buffer layer 160. The plurality of color filters 170 and the black matrix 180 may serve as an anti-reflection layer which absorbs external light to minimize or at least reduce the degradation of visibility and a contrast ratio of the foldable display device 100 due to the external light.

The black matrix 180 may be disposed on the touch sensor unit 150 or the second buffer layer 160. The black matrix 180 is disposed along a boundary of the sub pixels and includes an opening which exposes the sub pixel. The black matrix 180 divides each of the plurality of color filters 170. The black matrix 180 may be disposed so as to overlap the bank 125. Therefore, the color mixture between the sub pixels SP1, SP2, and SP3 may be minimized. Further, the black matrix 180 absorbs external light. Therefore, the degradation of the visibility and the contrast ratio of the foldable display device 100 due to the external light may be minimized.

The black matrix 180 may be formed of an organic material. The black matrix 180 includes a base resin and a black material. The base resin may be one or more selected from cardo based resin, epoxy-based resin, acrylate based resin, siloxane based resin, and polyimide, but is not limited thereto. The black material may be a black pigment selected from a carbon-based pigment, a metal oxide-based pigment, and an organic pigment. For example, the carbon-based pigment may be carbon black. For example, the metal oxide-based pigment may be titanium black (TiNxOy) or Cu—Mn—Fe based black pigment, but is not limited thereto. For example, the organic pigment may be selected from lactam black, perylene black, and aniline black, but is not limited thereto. Further, as the black material, a RGB black pigment including a red pigment, a blue pigment, and a green pigment may be used.

The plurality of color filters 170 are disposed on the encapsulation layer 140. The plurality of color filters 170 may be disposed on the touch sensor unit 150 or the second buffer layer 160. Further, the plurality of color filters 170 are disposed to be in direct contact with the second buffer layer 160 and may be disposed to cover a partial area of the black matrix 180. The plurality of color filters 170 absorb external light to minimize or at least reduce degradation of the visibility and the contrast ratio due to the external light and improve a color reproductivity. The plurality of color filters 170 are disposed on the encapsulation layer 140 to improve the luminous efficiency and omit a polarizer or a polarization film.

The plurality of color filters 170 are disposed so as to correspond to sub pixels disposed there below. At this time, referring to FIG. 4, the plurality of color filters 170 include color filters 171a, 172a, and 173a corresponding to the plurality of sub pixels SP1, SP2, and SP3 disposed in the folding area FA and color filters 171b, 172b, and 173b corresponding to the plurality of sub pixels SP1, SP2, and SP3 disposed in the non-folding areas NFA1 and NFA2. The color filters 171a, 172a, and 173a disposed in the folding area FA and the color filters 171b, 172b, and 173b disposed in the non-folding areas NFA1 and NFA2 have different shapes. Specifically, the color filters 171a, 172a, and 173a disposed in the folding area FA include at least one hole H1, H2, H3. However, in the color filters 171b, 172b, and 173b disposed in the non-folding areas NFA1 and NFA2, a hole is not formed. The holes H1, H2, and H3 will be described in detail below.

In the meantime, all color filters 170 disposed in the folding area FA and the non-folding areas NFA1 and NFA2 include first color filters 171a and 171b corresponding to the first sub pixel SP1, second color filters 172a and 172b corresponding to the second sub pixel SP2, and third color filters 173a and 173b corresponding to the third sub pixel SP3. When the first sub pixel SP1 is a red sub pixel, the first color filters 171a and 171b are red color filters, when the second sub pixel SP2 is a green sub pixel, the second color filters 172a and 172b are green color filters, and when the third sub pixel SP3 is a blue sub pixel, the third color filters 173a and 173b are blue color filters. The first color filters 171a and 171b transmit red light. Here, the wavelength of red light may be approximately 620 nm to 750 nm. The second color filters 172a and 172b transmit green light. Here, the wavelength of green light may be approximately 495 nm to 570 nm. The third color filters 173a and 173b transmit blue light. Here, the wavelength of blue light may be approximately 440 nm to 495 nm.

Each color filter 170 includes a transparent base resin and a color development material. For example, the transparent base resin may be one selected from polyacrylate, polymethyl methacrylate, polyimide, polyvinyl alcohol, polyethylene, polypropylene, polystyrene, and polyethylene terephthalate, but is not limited thereto.

The color development material absorbs light in a specific wavelength band and transmits light in the other wavelength band. For example, the red color filter includes a red color development material which transmits light in a red wavelength band and absorbs light in green and blue wavelength bands. For example, a red color development material may be a parylene based compound or a diketo-pyrrolopyrrole based compound. For example, a green color development material may be a phthalocyanine based compound. For example, a blue color development material may be a copper phthalocyanine based compound or an anthraquinone based compound. However, the color development material is not limited thereto and any material which transmits light in the red, blue, and green wavelength bands may be used without limitations.

As each color filter 170 is disposed so as to correspond to the color of each corresponding sub pixel SP1, SP2, SP3, internal light emitted from each of the first sub pixel SP1, the second sub pixel SP2, and the third sub pixel SP3 passes through the color filter 170. For example, red light emitted from the first sub pixel SP1 passes through the first color filters 171a and 171b. In contrast, when external light is incident, external light corresponding to an absorption wavelength of a color development material included in each color filter 170 is absorbed by the color filter 170. External light which is not absorbed by the color filter 170 is reflected from the cathode 133 to pass through the color filter 170 again. Reflected light corresponding to the absorption wavelength of the color development material included in each color filter 170 is absorbed by the color filter 170. Therefore, the degradation of the display quality due to the external light may be minimized or at least reduced.

In FIG. 3, it is illustrated that the color filter is independently disposed so as to correspond to each of the plurality of sub pixels SP1, SP2, and SP3, but is not limited thereto. The plurality of color filters 170 may be formed as a single layer. For example, the plurality of color filters 170 may be disposed as a single layer so as to cover upper portions of the second buffer layer 160 and the black matrix 180. In this case, the plurality of color filters 170 may include a base resin, a red development material, a green development material, and a blue development material, but is not limited thereto. Some development materials may be omitted and other color development materials may be further included in addition to the red development material, the green development material, and the blue development material, as needed.

Referring to FIG. 4, the color filters 171a, 172a, and 173a corresponding to the plurality of sub pixels SP1, SP2, and SP3 disposed in the folding area FA and the color filters 171b, 172b, and 173b corresponding to the plurality of sub pixels SP1, SP2, and SP3 disposed in the non-folding areas NFA1 and NFA2 may have different shapes. Specifically, the color filters 171a, 172a, and 173a disposed in the folding area FA include at least one hole H1, H2, H3. However, in the color filters 171b, 172b, and 173b disposed in the non-folding areas NFA1 and NFA2, a hole is not formed.

More specifically, each of the color filters 171a, 172a, and 173a disposed in the folding area FA includes at least one hole H1, H2, H3. For example, in the folding area FA, the first color filter 171a corresponding to the first sub pixel SP1 includes a first hole H1, the second color filter 172a corresponding to the second sub pixel SP2 includes a second hole H2, and the third color filter 173a corresponding to the third sub pixel SP3 may include a third hole H3.

Referring to FIG. 3, the first hole H1, the second hole H2, and the third hole H3 may have a circular shape, but are not limited thereto. For example, the first hole H1, the second hole H2, and the third hole H3 may have an oval shape or a polygonal shape. Further, the first hole H1, the second hole H2, and the third hole H3 may be formed as single holes, respectively, but are not limited thereto. Further, the first hole H1, the second hole H2, and the third hole H3 may be located in the middle of the first color filter 171a, the second color filter 172a, and the third color filter 173a, respectively, of the folding area FA, but are not limited thereto.

The holes H1, H2, and H3 formed in the color filters 171a, 172a, and 173a disposed in the folding area FA may improve the transmittance of the foldable display device 100. For the anti-reflection function, the plurality of color filters 170 and the black matrix 180 disposed above the organic light emitting diode 130 may reduce the reflectance and improve the color reproductivity, but reduce the transmittance of the foldable display device 100. Therefore, the plurality of holes H1, H2, and H3 is formed in the plurality of color filters 170 to compensate for the reduced transmittance.

Further, the holes H1, H2, and H3 formed in the color filters 171a, 172a, and 173a disposed in the folding area FA may suppress the rainbow mura in the folding area FA. The plurality of color filters 170 disposed above the organic light emitting diode 130 is formed to have an area larger than the emission area of the organic light emitting diode 130 to ensure the viewing angle. That is, each color filter 170 is formed to have an area larger than an area of the anode 131 exposed by the bank 125. In this case, the rainbow mura is generated and the reflective visibility may be degraded by interference of light caused by interference between a regular pattern shape of the color filters and the anodes which are regularly disposed. This problem affects the image quality characteristic and persistent patterning may persist and cause problems with visibility. Therefore, one hole H1, H2, H3 is formed to assign an irregular pattern to suppress the rainbow mura.

In the meantime, referring to FIGS. 3 and 4, in the foldable display device 100 according to the exemplary embodiment of the present disclosure, the first hole H1, the second hole H2, and the third hole H3 have a circular shape in the plan view and are configured as single holes, respectively. At this time, a size of each hole may vary depending on a wavelength of light emitted from each sub pixel. Specifically, as mentioned above, the first sub pixel SP1 is a red sub pixel, the second sub pixel SP2 is a green sub pixel, and the third sub pixel SP3 is a blue sub pixel. At this time, in the folding area FA, the first hole H1 included in the first color filter 171a corresponding to the first sub pixel SP1 is larger than the second hole H2 included in the second color filter 172a corresponding to the second sub pixel SP2 and the third hole H3 included in the third color filter 173a corresponding to the third sub pixel SP3. Further, the third hole H3 included in the third color filter 173a corresponding to the third sub pixel SP3 is smaller than the second hole H2 included in the second color filter 172a corresponding to the second sub pixel SP2. That is, the sizes of the holes are formed in the order of the first hole H1 formed in the first color filter 171a corresponding to the red sub pixel, the second hole H2 formed in the second color filter 172a corresponding to the green sub pixel, and the third hole H3 formed in the third color filter 173a corresponding to the blue sub pixel.

In the meantime, when all the first hole H1, the second hole H2, and the third hole H3 have a circular shape, a diameter of the first hole H1 is equal to or smaller than a center wavelength of the first color filter 171a. Further, a diameter of the second hole H2 is equal to or smaller than a center wavelength of the second color filter 172a and a diameter of the third hole H3 is equal to or smaller than a center wavelength of the third color filter 173a. Within this range, the color mixture of the light from the light emitting diode is suppressed and the rainbow mura may be improved. Specifically, a diameter of the first hole H1 is 620 nm to 650 nm, a diameter of the second hole H2 is 495 nm to 550 nm, and a diameter of the third hole H3 may be 440 nm to 460 nm. For example, a diameter of the first hole H1 is 0.65 μm, a diameter of the second hole H2 is 0.53 μm, and a diameter of the third hole H3 is 0.46 μm. When the size of the hole satisfies the above condition, the color reproductivity of the foldable display device 100 may be improved.

An area of each hole in the plan view is 20% or lower of the area of the emission area of the sub pixel. When the area of the hole exceeds 20% of the area of the emission area of the sub pixel, a color coordinate is significantly changed and the reflectance of the foldable display device 100 is increased so that the anti-reflection function of the color filter and the black matrix may be reduced.

In the meantime, the first hole H1, the second hole H2, and the third hole H3 have a taper shape. Referring to FIG. 4, the taper shape refers to a shape that a size, for example, a diameter of the hole is reduced upwardly from the flexible substrate 110, with respect to the flexible substrate 110 on the cross-section. In other words, the color filters 171a, 172a, and 173a disposed in the folding area FA have a reversed taper shape on the cross-section. That is, each color filter 171a, 172a, 173a has a shape that a cross-sectional width is increased upwardly from the flexible substrate 110, with respect to the flexible substrate 110. That is, the color filter 171a, 172a, and 173a of the folding area FA have a reversed taper shape in the holes H1, H2, H3, respectively.

The color filters 171a, 172a, and 173a of the folding area FA have a reversed taper shape so that the adhesive strength with the over coating layer 190 disposed above the color filters 171a, 172a, and 173a may be increased. When the foldable display device 100 is folded, there is a problem in that the over coating layer 190 which protects and planarizes the color filters 171a, 172a, and 173a of the folding area FA is peeled off or cracked. However, the color filters 171a, 172a, and 173a have a reversed taper shape and the over coating layer 190 is filled in the holes H1, H2, and H3 formed in the color filters 171a, 172a, and 173a so that the adhesive strength may be significantly improved by the anchoring effect between the color filters 171a, 172a, and 173a and the over coating layer 190. By doing this, even with the repeated folding operation, the peeling and the crack of the color filters 171a, 172a, and 173a and the over coating layer 190 do not occur and the durability may be improved.

In FIG. 4, it is illustrated that the plurality of color filters 170 and the black matrix 180 which serve as an anti-reflection layer are disposed above the second buffer layer 160, but the present disclosure is not limited thereto. For example, the plurality of color filters 170 and the black matrix 180 may be disposed above the encapsulation layer 140 and the touch sensor unit 150 may be disposed on the plurality of color filters 170. In this case, a distance between the touch electrode 151 and the organic light emitting diode 130 and the thin film transistor TFT is increased to reduce a parasitic capacitance formed therebetween. Further, a distance from an outermost surface to which the touch is input to the touch electrode 151 is reduced to improve the touch sensitivity.

The over coating layer 190 is disposed so as to cover the plurality of color filters 170 and the black matrix 180. The over coating layer 190 is filled in the holes H1, H2, and H3. Therefore, the over coating layer 190 planarizes upper portions of the plurality of color filters 170 and the black matrix 180. For example, the over coating layer 190 may be formed of transparent resin, such as acrylic resin, silicon based resin, polyester based resin, and epoxy resin, but is not limited thereto.

In the meantime, the over coating layer 190 may include an UV absorbing layer. The UV absorbing layer blocks light with ultraviolet wavelength from external light incident to the foldable display device 100. The UV absorbing layer blocks light with a wavelength which is equal to or lower than 400 nm and transmits visible ray with a wavelength which exceeds approximately 400 nm. The UV absorbing layer may be formed of an organic material including an UV blocker or an UV absorber which blocks or absorbs light with a wavelength which is equal to or lower than 400 nm. The UV blocker or UV absorber may be used without limitation as long as the UV blocker or UV absorber is a material used in this technical field.

Light with the ultraviolet wavelength may cause the damage of the organic layer of the organic light emitting diode 130 through the holes H1, H2, and H3 formed in each color filters 170. Accordingly, the UV absorbing layer is formed on the color filter 170 in which the holes H1, H2, and H3 are formed and the black matrix 180 to suppress the damage of the organic light emitting diode 130.

The foldable display device according to the exemplary embodiment of the present disclosure includes a color filter corresponding to each sub pixel and has a structure in which at least one hole is formed in the color filter disposed in the folding area. External light is absorbed by the plurality of color filters to minimize or at least reduce degradation of the visibility and the contrast ratio due to the external light and improve a color reproductivity. Further, the external light reflection of the related art is suppressed and an optical film used to improve the reflective visibility may be omitted so that the folding performance may be improved. Further, in the foldable display device according to the exemplary embodiment of the present disclosure, a color filter of the folding area is formed to have a reversed taper shape in the hole so that a binding strength between the color filter and the over coating layer is improved. Therefore, the peeling or the crack of the over coating layer is suppressed even by the repeated folding operation to improve the durability.

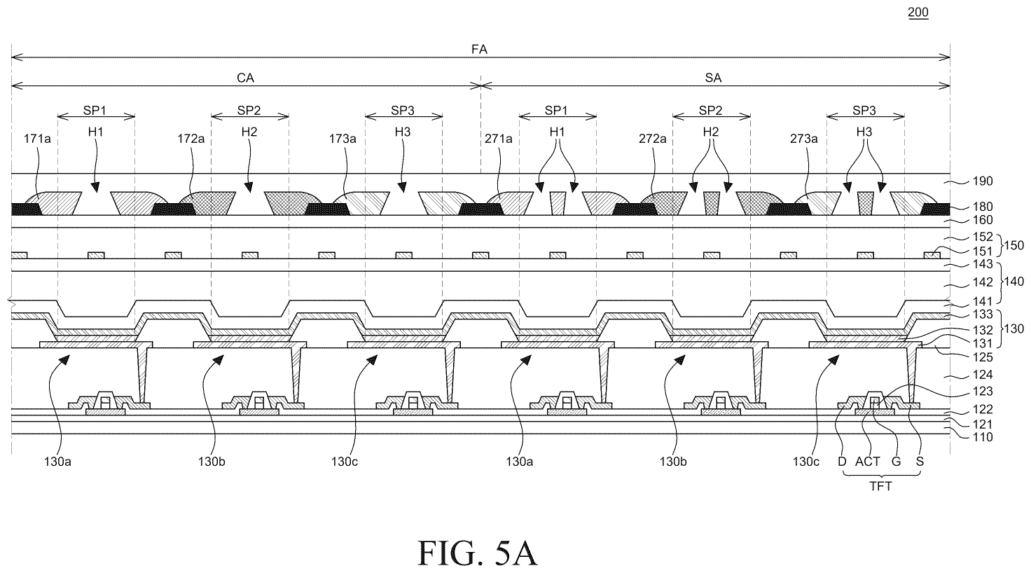

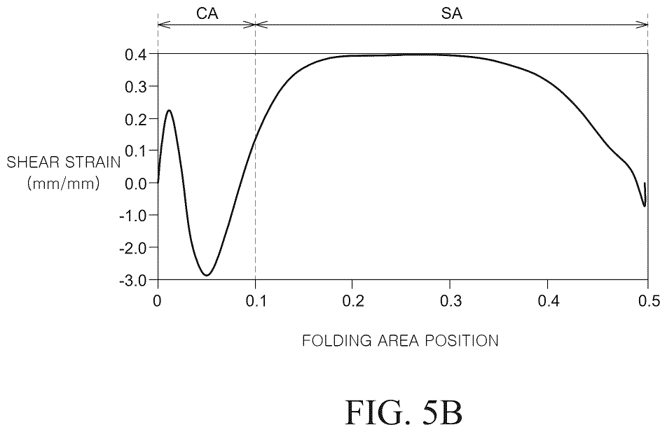

FIG. 5A is a schematic cross-sectional view of a foldable display device according to another exemplary embodiment of the present disclosure. A foldable display device 200 illustrated in FIG. 5A has the substantially same configurations as the foldable display device 100 illustrated in FIGS. 1 to 4 except that a shape of holes formed in a plurality of color filters is different, so that a redundant description will be omitted.

Referring to FIG. 5A, the folding area FA includes a folding center area CA and a folding shoulder area SA. The folding shoulder area SA refers to an area in the folding area FA which is the maximum tensile point during a folding operation. The folding shoulder area SA includes a boundary between the non-folding areas NFA1 and NFA2 which are not deformed during the folding operation and the folding area FA which is deformed. The folding center area CA refers to an area between the folding shoulder areas SA located on both sides in the folding area FA.

Referring to FIG. 5A, at least some of the plurality of color filters 271a, 272a, and 273a disposed in the folding area FA has the different number of holes from the other color filters. Specifically, the first color filter 271a, the second color filter 272a, and the third color filter 273a corresponding to the plurality of sub pixels SP1, SP2, and SP3 disposed in the folding shoulder area SA adjacent to the non-folding areas NFA1 and NFA2 have the larger number of holes than those of the color filters 171a, 172a, and 173a disposed in the folding center area CA. For example, each of the first color filter 271a, the second color filter 272a, and the third color filter 273a disposed in the folding shoulder area SA includes two first holes H1 (e.g., a pair), two second holes H2, and two third holes H3. Each of the first color filter 171a, the second color filter 172a, and the third color filter 173a disposed in the folding center area CA includes one first hole H1, one second hole H2, and one third hole H3.

Generally, in the foldable display device, the maximum folding stress is applied to the folding shoulder area SA adjacent to the boundary between the non-folding areas NFA1 and NFA2 and the folding area FA. Specifically, referring to FIG. 5B, when a center position of the folding area is assumed as 0 and a position of the folding area adjacent to the non-folding area is 0.5, it is confirmed that the shear strain is significantly increased from a position (0, 1) spaced apart from the center position (0) by a predetermined distance. Specifically, the shear strain may be maximum in a position spaced apart from the center position (0) by 0.2 to 0.4. At this time, FIG. 5B is a graph illustrating a shear strain of a general display device during the folding as it is adjacent to a non-display area from a center of a folding area.

That is, a large stress is applied to the color filters 271a, 272a, and 273a and the over coating layer 190 located in the folding area FA adjacent to the non-folding areas NFA1 and NFA2 to be easily cracked or peeled off. In order to solve this problem, the larger number of holes is formed in the color filters 271a, 272a, and 273a located in the folding shoulder area SA adjacent to the non-folding areas NFA1 and NFA2 than in the color filters 171a, 172a, and 173a of the folding center area CA. The binding strength between the color filters 271a, 272a, and 273a and the over coating layer 190 in the folding shoulder area SA may be further increased. In the meantime, the folding shoulder area SA may be an area with a width of a ratio of 0.4 with respect to the overall width of the folding area FA on both sides adjacent to the non-folding areas NFA1 and NFA2. Referring to FIG. 5B, the shear strain is maximum in a position spaced apart from the center position (0) of the folding center area CA by 0.2 to 0.4 so that the folding shoulder area may be defined as a position spaced apart from the center position (0) of the folding center area CA by 0.1 to 0.5.

In the meantime, in FIG. 5A, a structure in which two holes are formed in each of the first color filter 271a, the second color filter 272a, and the third color filter 273a of the folding shoulder area SA is illustrated, but the present disclosure is not limited thereto. For example, the more adjacent to the non-folding areas NFA1 and NFA2, the larger the number of holes in the folding shoulder area SA. Further, the first color filter 271a, the second color filter 272a, and the third color filter 273a which are the most adjacent to the non-folding areas NFA1 and NFA2 include the same number of holes and another first, second, and third color filters closer to the folding area FA may include the smaller number of holes.

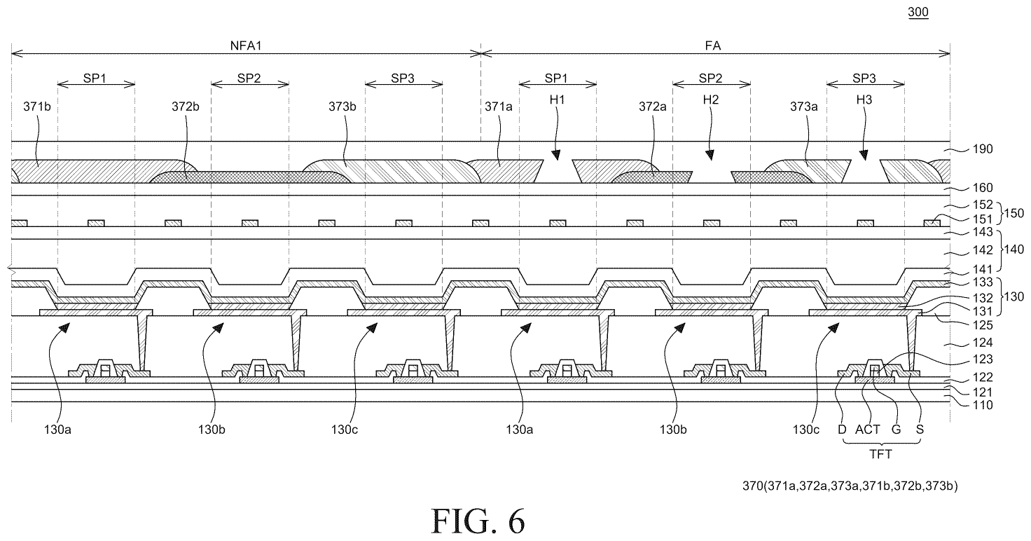

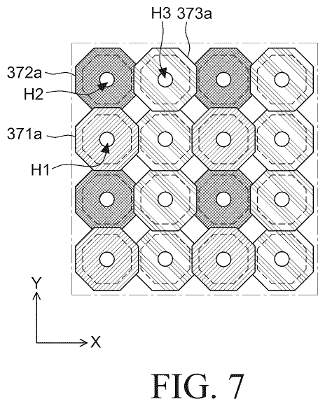

FIG. 6 is a schematic cross-sectional view of a foldable display device according to still another exemplary embodiment of the present disclosure. FIG. 7 is a schematic enlarged plan view for a partial area of a foldable display device illustrated in FIG. 6 according to an exemplary embodiment of the present disclosure. A foldable display device 300 illustrated in FIGS. 6 and 7 has the substantially same configurations as the foldable display device 100 illustrated in FIGS. 1 to 4 except that a black matrix is not included and a placement shape of a plurality of color filters 370 is different so that a redundant description will be omitted.

Referring to FIG. 6, a foldable display device 300 according to still another exemplary embodiment of the present disclosure has a structure in which two color filters overlap each other in an area overlapping a bank 125 along a boundary of sub pixels. At least two color filters may be disposed so as to overlap a bank 125 located between adjacent sub pixels. For example, first color filters 371a and 371b and second color filters 372a and 372b are disposed to overlap each other in a non-emission area between the first sub pixel SP1 and the second sub pixel SP2. The second color filters 372a and 372b and the third color filters 373a and 373b are disposed to overlap each other in a non-emission area between the second sub pixel SP2 and the third sub pixel SP3. The first color filters 371a and 371b and the third color filters 373a and 373b are disposed to overlap each other in a non-emission area between the first sub pixel SP1 and the third sub pixel SP3. Two overlapping color filters may absorb the external light instead of the black matrix, as compared with the foldable display device illustrated in FIGS. 1 to 4.

In the foldable display device 300 illustrated in FIGS. 6 and 7, the black matrix is not formed so that a total of four patterning processes for sequentially forming the black matrix and the first, second and third color filters is reduced to three processes to reduce the process steps. Referring to FIGS. 6 and 7, when the first sub pixel SP1 is a red sub pixel, the second sub pixel SP2 is a green sub pixel, and the third sub pixel SP3 is a blue sub pixel, the color filters may be patterned in the order of the second color filters 372a and 372b which are green color filters, the third color filters 373a and 373b which are blue color filters, and the first color filters 371a and 371b which are red color filters. However, the present disclosure is not limited thereto.

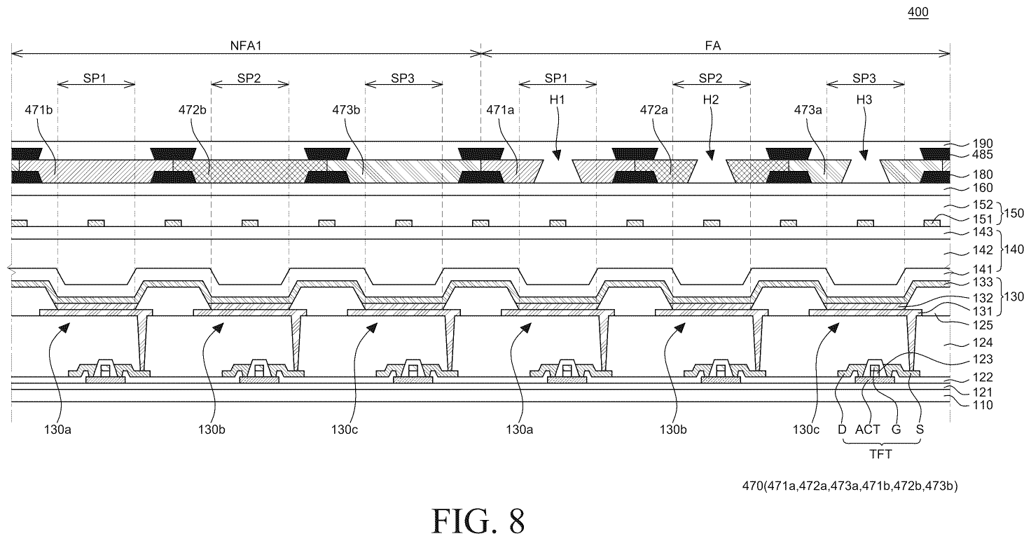

FIG. 8 is a schematic cross-sectional view of a foldable display device according to still another exemplary embodiment of the present disclosure. A foldable display device 400 illustrated in FIG. 8 has the substantially same configurations as the foldable display device 100 illustrated in FIGS. 1 to 4 except that a placement shape of a plurality of color filters is different and an auxiliary black matrix 485 is further provided, so that a redundant description will be omitted.

Referring to FIG. 8, a foldable display device 400 according to still another exemplary embodiment of the present disclosure has a structure in which an auxiliary black matrix 485 is disposed on a color filter 470 in an area overlapping the black matrix 180. As the auxiliary black matrix 485 is disposed on the color filter 470 in the non-emission area, the external light reflection is further reduced and the reflective visibility may be improved.

At this time, the auxiliary black matrix 485 has a reversed taper shape on the cross-section. The over coating layer 190 may be disposed so as to cover both a top surface and a side surface of the auxiliary black matrix 485. When the auxiliary black matrix 485 has a reversed taper shape, the over coating layer 190 which covers the color filter 470 and the auxiliary black matrix 485 may be additionally coupled to the auxiliary black matrix 485. That is, the over coating layer 190 is in contact with the auxiliary black matrix having a reversed taper shape together with the color filter 470 having a reversed taper shape formed by the hole to maximize the anchoring effect so that the adhesive strength of the over coating layer 190 may be significantly improved. By doing this, even with the repeated folding operation, the peeling and the crack of the color filter 470 and the over coating layer 190 do not occur and the durability may be further improved.

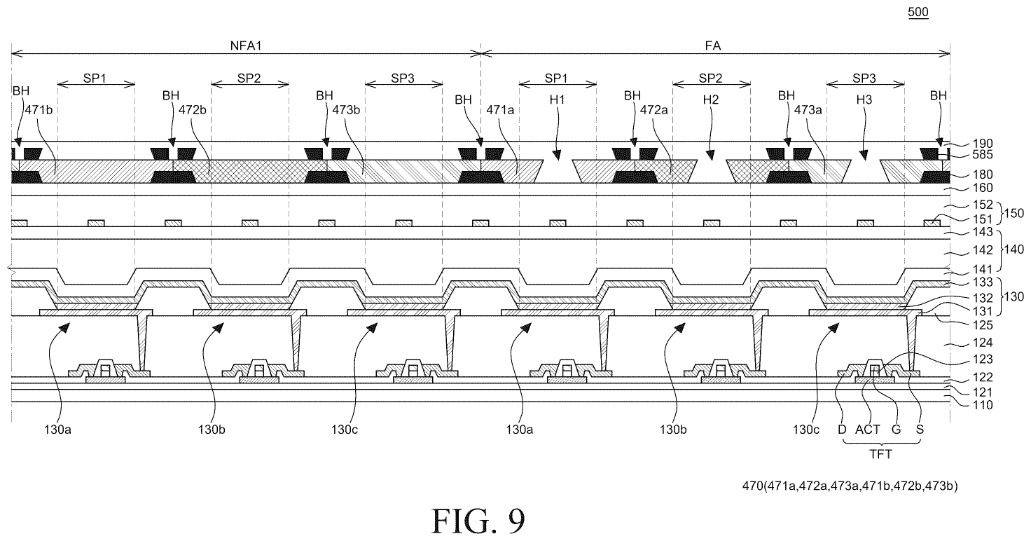

FIG. 9 is a schematic cross-sectional view of a foldable display device according to still another exemplary embodiment of the present disclosure. A foldable display device 500 illustrated in FIG. 9 has the substantially same configurations as the foldable display device 400 illustrated in FIG. 8 except that a BM hole BH is formed in an auxiliary black matrix 585, so that a redundant description will be omitted.

Referring to FIG. 9, a BM hole is formed in the auxiliary black matrix 585 disposed on the color filter 470 corresponding to the non-emission area. The over coating layer 190 is filled not only in the holes H1, H2, and H3 formed in the color filter 470, but also in the BM hole BH formed in the auxiliary black matrix 585 to be additionally in contact with the BM hole BH so that the adhesive strength of the over coating layer 190 may be further improved.

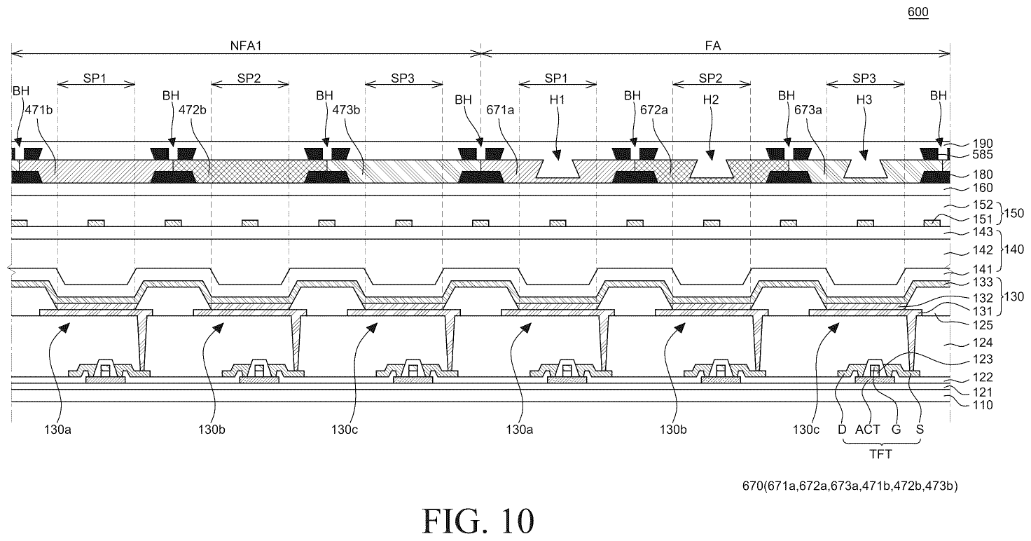

FIG. 10 is a schematic cross-sectional view of a foldable display device according to still another exemplary embodiment of the present disclosure. A foldable display device 600 illustrated in FIG. 10 has the substantially same configurations as the foldable display device 500 illustrated in FIG. 9 except that a structure of a plurality of color filters 670 is different, so that a redundant description will be omitted.

Referring to FIG. 10, in a foldable display device 600 according to still another exemplary embodiment of the present disclosure, a hole is not formed to expose the second buffer layer 160 below which the color filter 670 corresponding to each sub pixel is located, but a hole is formed to remain the color filter layer without exposing the second buffer layer 160 in the emission area. That is, as compared with the plurality of color filters 471b, 472b, and 473b disposed in the non-folding areas NFA1 and NFA2, the plurality of color filters 671a, 672a, and 673a disposed in the folding area FA is partially removed to be downwardly recessed. At this time, a recessed hole has a taper shape whose width is reduced upwardly from the flexible substrate 110 on the cross-section. In the meantime, as the color filter is partially removed to have a shape which is downwardly recessed, the color filters 671a, 672a, and 673a may conformally cover a side surface of the black matrix 180 and a top surface of the second buffer layer 160 which are located there below.

As illustrated in FIG. 10, when the plurality of color filters 671a, 672a, and 673a of the folding area FA has a recessed hole, the reflection by the external light may be reduced as compared with a hole which completely passes through the inside of the color filter. Further, as compared with a case in which the over coating layer 190 formed of an organic material is in direct contact with the second buffer layer 160 formed of an inorganic material in the hole, when the over coating layer 190 is in contact with the color filters 671a, 672a, and 673a formed of an organic material in the recessed hole, it is more advantageous in terms of the adhesive strength. Accordingly, the adhesive strength between the color filters 671a, 672a, and 673a and the over coating layer 190 is ensured to improve the durability for the folding and improve the reflective visibility, but also suppress the rainbow mura.

At this time, the thickness of each of the color filters 671a, 672a, and 673a disposed in the emission area defined by the black matrix 180 may be 20% to 60% of thickness of color filters 471b, 472b, and 473b which emit same color light in the non-folding areas NFA1 and NFA2. When the thickness of the color filters 671a, 672a, and 673a disposed in the folding area FA satisfies the above-mentioned range, the external light reflection by the cathode 133 in the display panel is blocked and a lateral coupling of the over coating layer 190 and the color filters 671a, 672a, and 673a may be ensured. Therefore, the durability for the folding may be improved. For example, when the thickness of the color filters 671a, 672a, and 673a disposed in the folding area FA is lower than 20%, a step filling characteristic is degraded due to the depth of the hole during the process of forming the over coating layer 190 to degrade the adhesive strength. When the thickness of the color filters 671a, 672a, and 673a disposed in the folding area FA exceeds 60%, the contact area between the color filters 671a, 672a, and 673a and the over coating layer 190 is reduced and the binding force with the over coating layer 190 according to the reversed taper shape of the color filter may be degraded.

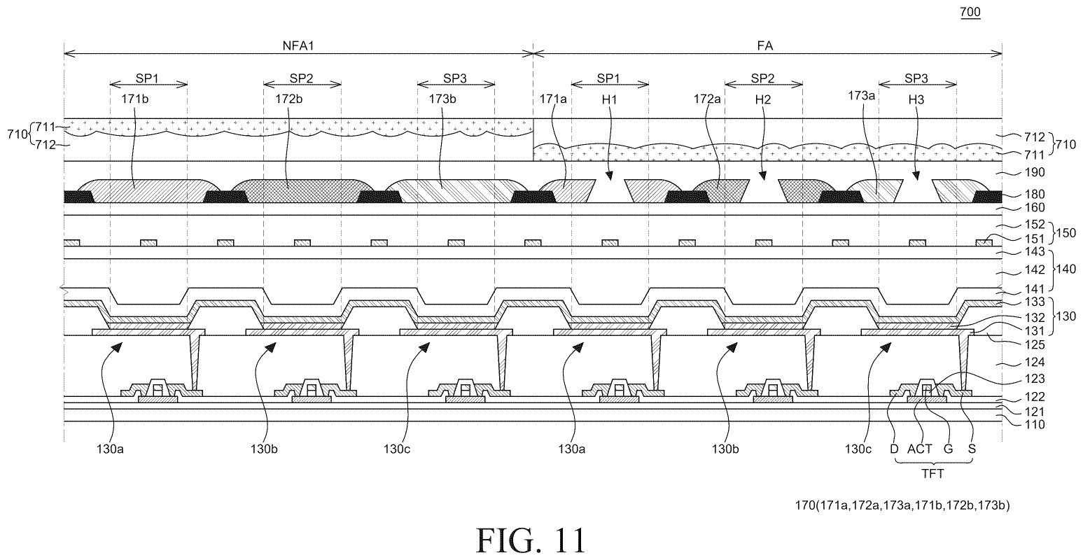

FIG. 11 is a schematic cross-sectional view of a foldable display device according to still another exemplary embodiment of the present disclosure. A foldable display device 700 illustrated in FIG. 11 has the substantially same configurations as the foldable display device 100 illustrated in FIGS. 1 to 4 except that an anti-mura layer 710 is further provided on the over coating layer, so that a redundant description will be omitted.

Referring to FIG. 11, the foldable display device 700 according to still another exemplary embodiment of the present disclosure includes an anti-mura layer 710 which suppresses the rainbow mura. The anti-mura layer 710 is disposed on the over coating layer 190 to suppress the degradation of the display quality due to the rainbow mura shape which is generated by the bank 125 which is exposed without being covered by the black matrix 180 due to a pull-back structure in which a width of the color filter 170 is formed to be larger than a width of the emission area.

The anti-mura layer 710 includes a pattern layer 711 having a specific pattern shape and a filling layer 712 which covers and planarizes the pattern layer 711. The filling layer 712 may have a different refractive index from that of the pattern layer 711. In the pattern layer 711, irregular patterns are formed to relieve the rainbow mura. For example, the pattern layer 711 includes patterns which are formed with irregular intervals with high and low heights or grooves. The pattern may have various shapes, such as asymmetric zigzag patterns, round waves, or grooves.

The filling layer 712 covers the pattern layer 711 to protect the pattern layer 711. For example, the filling layer 712 may be formed of a material which has a higher toughness and failure resistance than that of the pattern layer 711. At this time, referring to FIG. 11, in the folding area FA, the pattern layer 711 is located below the filling layer and in the non-folding areas NFA1 and NFA2, the filling layer 712 is located below the pattern layer. When the pattern layer 711 having a low toughness and failure resistance is disposed below the filling layer 712, a stress generated during the in-folding of the foldable display device 100 may be minimized.

In the foldable display device 700 illustrated in FIG. 11, instead of attaching a separate anti-mura film on the display panel using an adhesive layer to improve the rainbow mura in the related art, the anti-mura film is directly formed in the display panel to be embedded. As compared with the structure in which a separate anti-mura film is attached, in the foldable display device 700 illustrated in FIG. 11, an adhesive agent is removed so that the thickness of the display device is reduced to improve the folding performance. Further, in the foldable display device 700 illustrated in FIG. 11, the anti-mura layer 710 is embedded so that the pattern layer 711 is located to be close to the light emitting diode. Therefore, a diameter of light distribution output by the external light is reduced and interference with the pattern is also reduced so that it is advantageous to suppress the rainbow mura.

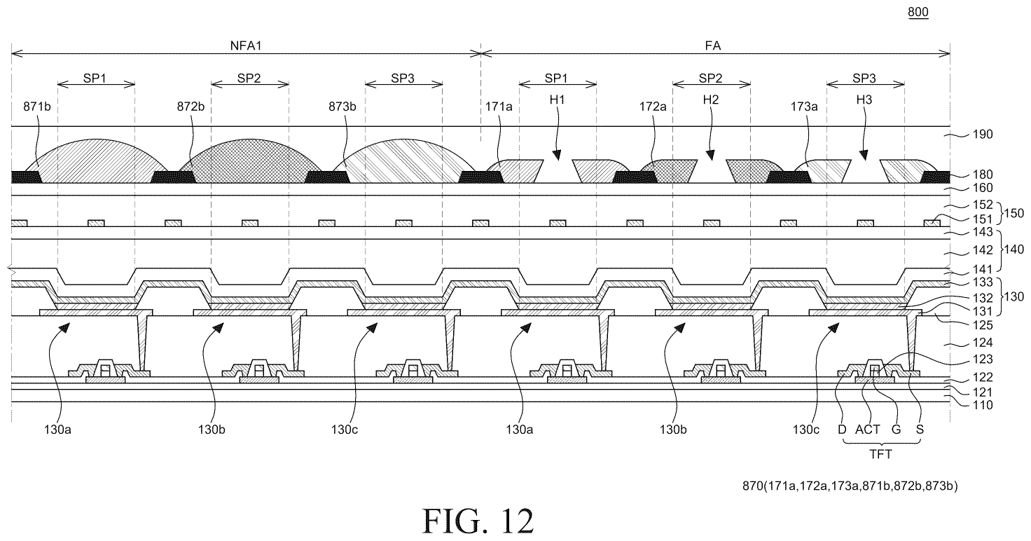

FIG. 12 is a schematic cross-sectional view of a foldable display device according to still another exemplary embodiment of the present disclosure. A foldable display device 800 illustrated in FIG. 12 has the substantially same configurations as the foldable display device 100 illustrated in FIGS. 1 to 4 except that the color filters 871b, 872b, and 873b disposed in the non-folding areas NFA1 and NFA2 has a different shape. Therefore, a redundant description will be omitted.

Referring to FIG. 12, the color filters 871b, 872b, and 873b disposed in the non-folding areas NFA1 and NFA2 have a lens shape with a convex upper surface. The color filters 871b, 872b, and 873b may have a top surface with a convex lens shape. When the color filters 871b, 872b, and 873b have a lens shape, the plurality of color filters 871b, 872b, and 873b disposed in the non-folding areas NFA1 and NFA2 may configure a plurality patterns having different areas. Further, the color filters 871b, 872b, and 873b have a refractive index different from that of the over coating layer 190 disposed on the color filters 871b, 872b, and 873b to serve as an anti-mural film.

That is, the anti-mura function is embedded by the shape of the color filter without attaching a separate anti-mural film so that the thickness of the display device is reduced to improve the folding performance.

The exemplary embodiments of the present disclosure can also be described as follows:

According to an embodiment of the present disclosure, there is provided a foldable display device. The foldable display device includes a flexible substrate which includes a plurality of sub pixels and includes a folding area and non-folding areas disposed on both sides of the folding area; a light emitting diode which is disposed on the flexible substrate and includes an anode, an emission layer, and a cathode; a bank which covers an edge of the anode to define an emission area; an encapsulation layer on the cathode; a plurality of color filters which is disposed on the encapsulation layer and corresponds to the plurality of sub pixels; and an over coating layer on the plurality of color filters. Each of the plurality of color filters disposed in the folding area includes at least one hole and the plurality of color filters has a reversed taper shape in the hole.

At least one hole may have a shape which is reduced upwardly on the cross-section.

A total area of a hole formed in each of the plurality of color filters disposed in the folding area may be 20% or smaller of an area of an emission area of a corresponding sub pixel.

The plurality of sub pixels may include a red sub pixel, a green sub pixel, and a blue sub pixel, the plurality of color filters may include a first color filter corresponding to the red sub pixel, a second color filter corresponding to the green sub pixel, and a third color filter corresponding to the blue sub pixel, and a size of a second hole of the second color filter may be smaller than a size of a first hole of the first color filter and may be larger than a size of a third hole of the third color filter.

All the first hole, the second hole, and the third hole may have a circular shape and a diameter of the first hole may be equal to or smaller than a center wavelength of the first color filter, a diameter of the second hole is equal to or smaller than a center wavelength of the second color filter, and a diameter of the third hole may be equal to or smaller than a center wavelength of the third color filter.

The diameter of the first hole may be 620 nm to 650 nm, the diameter of the second hole may be 495 nm to 550 nm, and the diameter of the third hole may be 440 nm to 460 nm.

The number of holes of the color filter disposed in the folding area adjacent to the non-folding area may be larger than the number of holes of the color filter disposed in the center of the folding area.

At least two color filters, among the plurality of color filters, may be disposed so as to overlap a bank located between adjacent sub pixels.

The plurality of sub pixels may include a red sub pixel, a green sub pixel, and a blue sub pixel, the plurality of color filters may include a first color filter corresponding to the red sub pixel, a second color filter corresponding to the green sub pixel, and a third color filter corresponding to the blue sub pixel, and the first color filter and the second color filter may be disposed so as to overlap each other in a non-emission area between the red sub pixel and the green sub pixel, the second color filter and the third color filter may be disposed so as to overlap each other in a non-emission area between the green sub pixel and the blue sub pixel, and the first color filter and the third color filter may be disposed so as to overlap each other in a non-emission area between the red sub pixel and the blue sub pixel.

The foldable display device may further comprise a black matrix which divides the plurality of color filters and is at least partially disposed below the plurality of color filters; and an auxiliary black matrix which is located between adjacent sub pixels and is disposed on the plurality of color filters so as to overlap the black matrix.

The auxiliary black matrix may have a reversed taper shape and the over coating layer may be disposed so as to cover both a top surface and a side surface of the auxiliary black matrix.

The auxiliary black matrix may include a BM hole which exposes at least a part of the color filter there below and the over coating layer may be filled in the BM hole.

At least one hole may overlap at least a part of the emission area and at least one hole may be downwardly recessed without passing through the color filter.

In the folding area, a thickness of a color filter overlapping the emission area may be 20% to 60% of a thickness of a color filter which emits the same color light in the non-folding area.

A color filter disposed in the non-folding area may have a top surface with a convex lens shape and the color filter and the over coating layer may have different refractive indices.

The foldable display device may further comprise an anti-mura layer which is disposed on the over coating layer so as to be in direct contact and includes a pattern layer having a specific pattern shape; and a filling layer covering the pattern layer and having a different refractive index from that of the pattern layer.

In the folding area, the pattern layer may be disposed to be closer to the light emitting diode than the filling layer and in the non-folding area, the filling layer may be disposed to be closer to the light emitting diode than the pattern layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all embodiments and do not limit the present disclosure. The protective scope of the present disclosure should be construed based on the following claims, and all the technical concepts in the equivalent scope thereof should be construed as falling within the scope of the present disclosure.

What is claimed is:

1. A foldable display device, comprising:
a flexible substrate having a plurality of sub pixels on the flexible substrate, the flexible substrate including a folding area and non-folding areas on both sides of the folding area;
a light emitting diode on the flexible substrate, the light emitting diode including an anode, an emission layer, and a cathode;
a bank that covers an edge of the anode to define an emission area;
an encapsulation layer on the cathode;
a plurality of color filters on the encapsulation layer, the plurality of color filters corresponding to the plurality of sub pixels; and
an over coating layer on the plurality of color filters,
wherein each of the plurality of color filters in the folding area includes at least one hole and the plurality of color filters have a reversed taper shape in the at least one hole.

2. The foldable display device according to claim 1, wherein at least one hole has a shape which is reduced upwardly on a cross-section of the foldable display device.

3. The foldable display device according to claim 1, wherein a total area of a hole in each of the plurality of color filters in the folding area is 20% or smaller of an area of an emission area of a corresponding sub pixel from the plurality of sub pixels.

4. The foldable display device according to claim 1, wherein the plurality of sub pixels includes a red sub pixel, a green sub pixel, and a blue sub pixel, the plurality of color filters includes a first color filter corresponding to the red sub pixel, a second color filter corresponding to the green sub pixel, and a third color filter corresponding to the blue sub pixel, and a size of a second hole of the second color filter is smaller than a size of a first hole of the first color filter and is larger than a size of a third hole of the third color filter.

5. The foldable display device according to claim 4, wherein all of the first hole, the second hole, and the third hole have a circular shape and a diameter of the first hole is equal to or smaller than a center wavelength of the first color filter, a diameter of the second hole is equal to or smaller than a center wavelength of the second color filter, and a diameter of the third hole is equal to or smaller than a center wavelength of the third color filter.

6. The foldable display device according to claim 5, wherein the diameter of the first hole is in a range from 620 nm to 650 nm, the diameter of the second hole is in a range from 495 nm to 550 nm, and the diameter of the third hole is in a range from 440 nm to 460 nm.

7. The foldable display device according to claim 1, wherein a number of holes of a color filter from the plurality of color filters that is in the folding area adjacent to a non-folding area from the non-folding areas is larger than a number of holes of a color filter from the plurality of color filters that is in a center of the folding area.

8. The foldable display device according to claim 1, wherein at least two color filters from the plurality of color filters overlap a bank located between adjacent sub pixels from the plurality of sub pixels.

9. The foldable display device according to claim 1, further comprising:
a black matrix that divides the plurality of color filters and is at least partially below the plurality of color filters; and
an auxiliary black matrix between adjacent sub pixels from the plurality of sub pixels and is on the plurality of color filters so as to overlap the black matrix.

10. The foldable display device according to claim 9, wherein the auxiliary black matrix has a reversed taper shape and the over coating layer covers both a top surface and a side surface of the auxiliary black matrix.

11. The foldable display device according to claim 10, wherein the auxiliary black matrix includes a black matrix hole which exposes at least a part of a color filter from the plurality of color filters there below and the over coating layer is filled in the black matrix hole.

12. The foldable display device according to claim 1, wherein at least one hole overlaps at least a part of the emission area and at least one hole is downwardly recessed without passing through a color filter from the plurality of color filters.

13. The foldable display device according to claim 12, wherein in the folding area, a thickness of a color filter from the plurality of color filters that overlaps the emission area is 20% to 60% of a thickness of a color filter from the plurality of color filters that emits a same color light in a non-folding area from the non-folding areas.

14. The foldable display device according to claim 1, wherein a color filter from the plurality of color filters that is in a non-folding area from the non-folding areas that has a top surface with a convex lens shape and the color filter and the over coating layer have different refractive indices.

15. The foldable display device according to claim 1, further comprising:
an anti-mura layer on the over coating layer so as to be in direct contact with the over coating layer, the anti-mura layer including:
a pattern layer having a specific pattern shape; and
a filling layer covering the pattern layer, the filling layer having a different refractive index from that of the pattern layer.

16. The foldable display device according to claim 15, wherein in the folding area, the pattern layer is close to the light emitting diode and in a non-folding area from the non-folding areas, the filling layer is close to the light emitting diode.

17. The foldable display device according to claim 15, wherein the pattern layer includes patterns which are formed with irregular intervals or the filling layer is formed of a material which has a higher toughness than that of the pattern layer.

18. The foldable display device according to claim 1, wherein the color filter disposed in the non-folding areas does not include a hole.

19. The foldable display device according to claim 1, further comprising:
a touch sensor unit disposed on the encapsulation layer;
a buffer layer disposed on the touch sensor unit;
a black matrix which divides the plurality of color filters; and
an auxiliary black matrix having a reversed taper shape and disposed on the color filter in an area overlapping the black matrix,
wherein the plurality of color filters and the black matrix are disposed on the buffer layer.

20. The foldable display device according to claim 19, wherein the auxiliary black matrix includes a BM hole which exposes at least a part of the color filter there below and
the over coating layer is filled in the BM hole.
